(19) United States
(12) Patent Application Publication
(10) Pub. No.: US 2014/0231016 A1
(43) Pub. Date: Aug. 21, 2014

(54) PLASMA PROCESSING APPARATUS

(71) Applicant: TOKYO ELECTRON LIMITED, Tokyo (JP)

(72) Inventors: Jun YOSHIKAWA, Miyagi (JP); Toshihisa NOZAWA, Miyagi (JP); Naoki MATSUMOTO, Miyagi (JP); Peter L. G. VENTZEK, Austin, TX (US)

(73) Assignee: TOKYO ELECTRON LIMITED, Tokyo (JP)

(21) Appl. No.: 14/159,546

(22) Filed: Jan. 21, 2014

(30) Foreign Application Priority Data
Feb. 19, 2013 (JP) 2013-030004

(51) Int. Cl. H01J 37/32

(52) U.S. Cl. CPC H01J 37/32192
USPC 156/345.41

(57) ABSTRACT

Disclosed is a plasma processing apparatus including a processing container that defines a processing space, a mounting table, and a microwave introducing antenna. The mounting table includes a mounting region where a workpiece accommodated in the processing container is mounted. The microwave introducing antenna includes a dielectric window installed above the mounting table. The dielectric window includes a bottom surface region that adjoins the processing space. The bottom surface region is configured in an annular shape so as to limit a region where a surface wave is propagated to a region above an edge of the mounting region.

### CROSS-REFERENCE TO RELATED APPLICATIONS

This application is based on and claims priority from Japanese Patent Application No. 2013-30004, filed on Feb. 19, 2013, with the Japan Patent Office, the disclosure of which is incorporated herein in its entirety by reference.

### TECHNICAL FIELD

The present disclosure relates to a plasma processing apparatus.

### BACKGROUND

In manufacturing a device such as, for example, a semiconductor device, a plasma processing apparatus is used for various processings such as, for example, an etching and a film forming. There are various types of plasma processing apparatuses, including a capacitively coupled plasma processing apparatus and an inductively coupled plasma processing apparatus, for example. However, plasma processing apparatuses using microwaves as a plasma source have received attention.

International Publication WO2011/125524 discloses a plasma processing apparatus using microwaves as a plasma source. The plasma processing apparatus disclosed in International Publication WO 2011/125524 is provided with a processing container configured to define a processing space, a mounting table configured to mount a workpiece thereon, and a microwave introducing antenna. The microwave introducing antenna includes a disc-shaped dielectric window and the dielectric window is provided above the mounting table with the processing space being interposed therebetween. The plasma processing apparatus excites a processing gas supplied to the processing container using surface waves propagated from the bottom surface of the dielectric window so as to generate plasma within the processing container.

### SUMMARY

According to an aspect of the present disclosure, a plasma processing apparatus that generates plasma of a processing gas so as to process a workpiece is provided. The plasma processing apparatus includes a processing container that defines a processing space, a mounting table, and a microwave introducing antenna. The mounting table includes a mounting region where a workpiece accommodated in the processing container is mounted. The microwave introducing antenna includes a dielectric window provided above the mounting table. The dielectric window includes a bottom surface region which adjoins the processing space. The bottom surface region is configured in an annular shape so as to limit a region where a surface wave is propagated to a region above an edge of the mounting region.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating a plasma processing apparatus according to an exemplary embodiment.

FIG. 2 is a cross-sectional view illustrating an antenna, a gas shower unit, and a mounting table of the plasma processing apparatus illustrated in FIG. 1 in an enlarged scale.

FIG. 3 is a bottom view illustrating the bottom area and slots of the dielectric window.

FIG. 4 is a view schematically illustrating a plasma processing apparatus simulated in Simulation 1.

FIGS. 5A and 5B are bottom views illustrating the bottom surface region and slots of the dielectric window for describing settings of Simulations 5 to 10.

FIGS. 6A and 6B are graphs that represent electric field strength distributions calculated in Simulations 5 to 10.

FIG. 7 is a view for describing a system set in Simulation 11.

FIG. 8 is a graph that represents the results calculated by Simulation 11.

FIGS. 9A and 9B are views for describing a plasma processing apparatus according to another exemplary embodiment.

FIG. 10 is a bottom view illustrating the bottom surface region and slots of the dielectric window in a plasma processing apparatus according to still another exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the plasma processing apparatus disclosed in International Publication No. WO2011/125524, plasma is generated just below the dielectric window. However, the plasma generation position may be changed when, for example, the pressure within the processing container or a gas species of the process gas is changed. In some cases, the plasma generation position may be changed even during a process. This phenomenon is referred to as a “mode hop”. The mode hop occurs due to the following reasons. That is, the wavelength of a surface wave propagated on a bottom surface of the dielectric window relies on the material of the dielectric window and an electron density in an interface between the bottom surface of the dielectric window and the plasma. Accordingly, when a pressure within the processing container and the gas species of the processing gas are changed, for example, the electron density of the plasma is changed so that the wavelength of the surface wave is varied. As a result, a field-strength distribution just below the dielectric window is varied so that the plasma generating position is also varied. When the mode hop occurs, variation of a processing in a plane of a workpiece may be caused.

In addition, development of a plasma processing apparatus capable of processing a workpiece having a diameter larger than 300 mm, for example, a diameter of 450 mm has been recently requested. In a plasma processing apparatus that processes an object having a larger diameter, the diameter (outer diameter) is also inevitably increased. When the diameter of the dielectric window is increased, the area of a region where the mode hop may occur, i.e. the bottom surface of the dielectric window is also increased. As a result, the variation of the processing in a plane of the workpiece which is caused by the mode hop becomes more remarkable.

Accordingly, what is requested in the present technical field is a plasma processing apparatus capable of controlling a plasma generation position.

An aspect of the present disclosure provides a plasma processing apparatus that generates plasma of a processing gas so as to process a workpiece. The plasma processing apparatus includes a processing container that defines a processing space, a mounting table, and a microwave introducing antenna. The mounting table includes a mounting region where a workpiece accommodated in the processing container is mounted. The microwave introducing antenna includes a dielectric window provided above the mounting table. The dielectric window includes a bottom surface region which adjoins the processing space. The bottom surface region is configured in an annular shape so as to limit a region where a surface wave is propagated to a region above an edge of the mounting region.

The inventor of the present application has founded that, in order to reduce variation of a processing according to an in-plane position of a workpiece, it is required to reduce variation in plasma density in a diametric direction just above the workpiece, that is, to make the plasma density approximately uniform or to increase the plasma density just above an edge of the workpiece to be higher than the plasma density just above a center of the workpiece. For this purpose, it is desirable to generate plasma at a region above the edge of the workpiece just below the dielectric window and to diffuse the plasma. In the plasma processing apparatus according to the above-described aspect, the region of the dielectric window which adjoins the processing space is limited to the bottom surface region, the bottom surface region is configured in an annular shape, and a region where a surface wave is propagated is limited to a region above an edge of the mounting region. Accordingly, a plasma generating region just below the dielectric window may be limited to a region above an edge of the workpiece. As a result, the variation of the processing according to an in-plane position of the workpiece may be reduced.

In an exemplary embodiment, the plasma processing apparatus may further include a mechanism configured to adjust a distance between the mounting table and the dielectric window. With the exemplary embodiment, the plasma density distribution in the diametric direction just above the work piece may be adjusted by adjusting the distance between the mounting table and the dielectric window. For example, a plasma density distribution in which the plasma density just above the edge of the workpiece becomes higher than the plasma density or a plasma density distribution opposite thereto may be formed.

In an exemplary embodiment, the bottom surface region of the dielectric window may include a plurality of recesses arranged in a circumferential direction. In another exemplary embodiment, the microwave introducing antenna includes a slot plate which is formed with a plurality of slots configured to radiate a microwave in relation to the dielectric window, the plurality of slots are arranged along one or more circular arcs above the bottom surface region, and the plurality of recesses are provided to be positioned vertically below the plurality of slots. With these exemplary embodiments, the plasma generating position may be controlled to the inside of the recesses of the bottom surface region of the dielectric window.

As described above, according to exemplary embodiments, a plasma processing apparatus capable of controlling a plasma generating position is provided.

Hereinafter, various exemplary embodiments will be described with reference to accompanying drawings. In the drawings, the same symbols will be allocated for the same or corresponding portions.

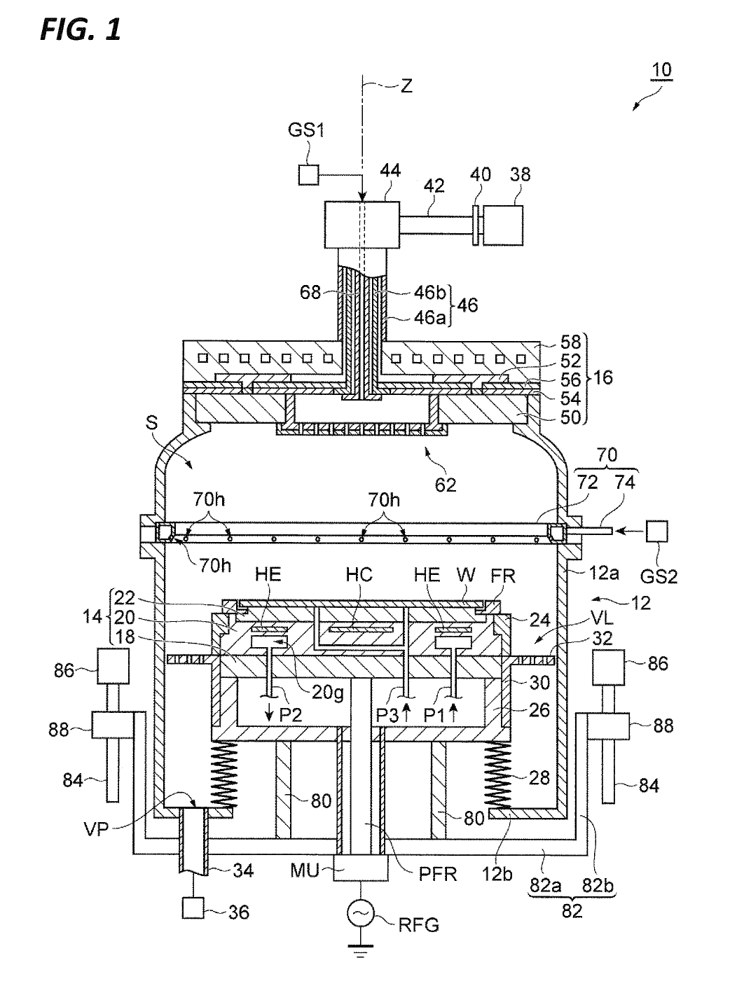

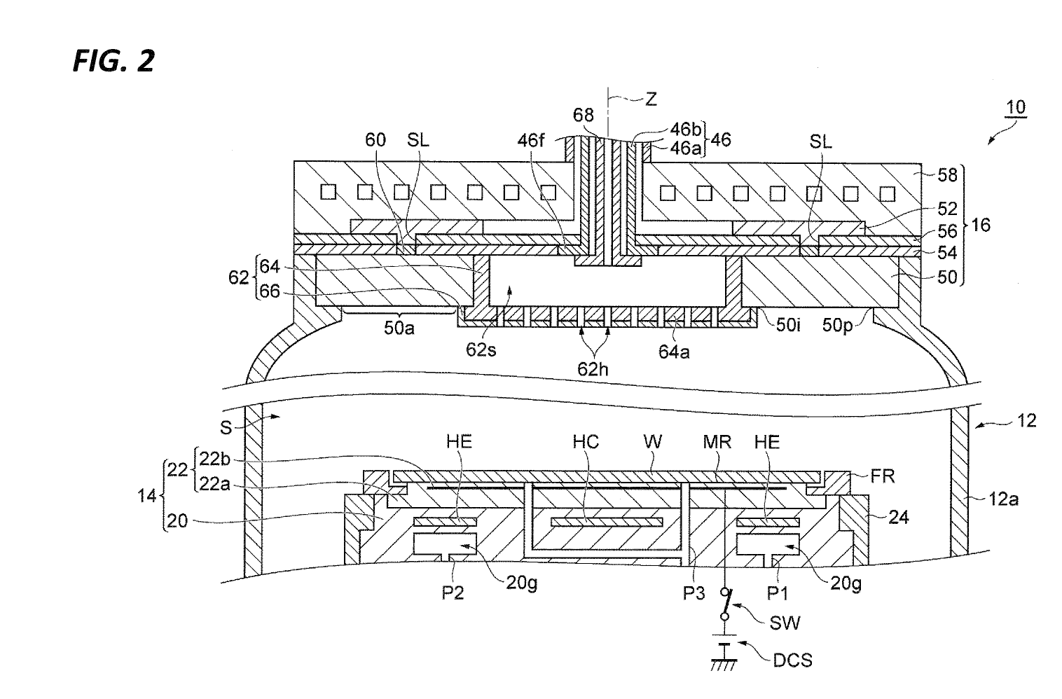

First, a plasma processing apparatus according to an exemplary embodiment will be described. FIG. 1 is a view schematically illustrating a plasma processing apparatus according to an exemplary embodiment. FIG. 1 schematically illustrates a cross-sectional view of the construction of the plasma processing apparatus 10. In addition, FIG. 2 is a cross-sectional view illustrating an antenna, a gas shower unit, and a mounting table of the plasma processing apparatus illustrated in FIG. 1 in an enlarged scale. As illustrated in FIGS. 1 and 2, the plasma processing apparatus 10 includes a processing container 12, a mounting table 14, and an antenna 16.

The processing container 12 defines a processing space S configured to accommodate a workpiece (wafer) W. The processing container 12 may include a side wall 12a and a bottom portion 12b. The side wall 12a has a substantially cylindrical shape extending in an axis Z extending direction (“axis Z direction”). The axis Z is an axis that passes the center of the wafer W mounted on the mounting table 14 in the vertical direction. The central axis of the side wall 12a may approximately coincide with the axis Z.

The side wall 12a is made of a metallic material such as, for example, aluminum. The inner surface of the side wall 12a is subjected to an alumite processing or coated with a material such as, for example, Y₂O₃. The diameter of the side wall 12a is determined according to the wafer W to be processed therein. For example, a wafer W having a diameter of 450 mm is processed, the diameter of the side wall 12a may be, for example, 750 mm. The top end of the side wall 12a is opened. The opening at the top end of the side wall 12a is closed by a dielectric window 50 and a gas shower unit 62 which will be described later. Further, a sealing member such as, for example, an O-ring, may be interposed between the dielectric window 50 and the top end of the side wall 12a.

The mounting table 14 is installed inside the processing container 12. In an exemplary embodiment, the mounting table 14 includes a plate 18, a base 20 and an electrostatic chuck 22. The plate 18 is a substantially disc-shaped metallic member and is made of, for example, aluminum. The plate 18 functions as a radio frequency electrode.

A radio frequency power source RFG that generates a radio frequency bias power is connected to the plate 18 through a matching unit MU and a power feeding rod PFR. The radio frequency power source RFG outputs a radio frequency bias power having a frequency suitable for controlling energy of ions drawn to the wafer W, for example, 13.65 MHz. The matching unit MU accommodates a matching device configured to match impedance of the radio frequency power source RFG side and impedance of a load side mainly of, for example, an electrode, plasma and the processing container 12. A blocking condenser that generates self-bias may be included inside the matching device.

A base 20 is mounted on the plate 18. The base 20 is a substantially disc-shaped metallic member and is made of, for example, aluminum. In an exemplary embodiment, an insulation member 24 is provided along the outer peripheral surface of the base 20. The insulation member 24 is made of, for example, quartz and protects the outer peripheral surface of the base 20.

The electrostatic chuck 22 is installed on the central region of the top surface of the base 20. The top surface of the electrostatic chuck 22 functions as a mounting region MR on which the wafer W is mounted. The above-mentioned axis Z vertically passes the center of the mounting region MR. The electrostatic chuck 22 maintains the wafer W by electrostatic attraction force.

In an exemplary embodiment, the electrostatic chuck 22 includes an electrode film 22b provided within a substantially disc-shaped dielectric film 22a. A direct current power source DCS is connected to the electrode film 22b through a switch SW. The electrostatic chuck 22 may attract and maintain the wafer W on the top surface thereof by Coulomb force generated by the direct current applied from the direct current power source DCS. At the diametrically outside of the electrostatic chuck 22, a focus ring FR is installed to surround the periphery of the wafer W in an annular shape.

In an exemplary embodiment, the mounting table 14 is provided with a temperature control mechanism configured to control the temperature of the wafer W. As an example of a temperature control function, an annular coolant chamber 20g extending in a circumferential direction is provided inside the base 20. In the coolant chamber 20g, a coolant, for example, cooling water of a predetermined temperature, is supplied to be circulated from a chiller unit through pipes P1, P2. In addition, in the plasma processing apparatus 10, a heat transfer gas, for example, He gas, from a heat transfer gas supply unit is supplied to a space between the top surface of the electrostatic chuck 22 and the back surface of the wafer W through a pipe P3.

In an exemplary embodiment, the plasma processing apparatus 10 may further include heaters HC, HE. The heater HC is installed inside the base 20. Within the base 20, the HC is installed in a region below the central portion of the mounting region MR, i.e. in a region crossing the axis Z. In addition, the heater HE is installed inside the base 20 and extends in an annular shape to surround the heater HC. The heater HE is installed below an edge area of the mounting region MR. In such an example, the temperature of the wafer W may be controlled by the coolant flowing in the coolant chamber 20g, the heat transfer gas supplied to the space between the top surface of the electrostatic chuck 22 and the back surface of the wafer W, and the heaters HC, HE.

As illustrated in FIG. 1, the mounting table 14 is supported by a cylindrical support unit 26. Specifically, the mounting table 14 is mounted on the top of the cylindrical support unit 26. In addition, a cylindrical bellows 28 is interposed between the edge of the bottom surface of the cylindrical support unit 26 and the bottom portion 12b of the processing container 12. The bellows 28 is extendible/retractable according to the vertical movement of the mounting table 14 and the support unit 26 by a driving mechanism so as to maintain the sealing of the gap between the support unit 26 and the bottom portion 12b of the processing container 12. The driving mechanism will be described later.

In an exemplary embodiment, an insulation member 30 is installed along the outer peripheral surface of the support unit 26. The insulation member 30 may be made of for example, quartz. An exhaust passage VL is formed between the insulation member 24, the insulation member 30 and the bellows 28, and the inner surface of the processing container 12. An annular baffle plate 32 formed with a plurality of through holes is installed at the middle of the exhaust passage VL in the axis Z direction. The baffle plate 32 is integrated with the insulation member 30 in the exemplary embodiment illustrated in FIG. 1.

The exhaust passage VL is connected to an exhaust pipe 34 that provides an exhaust port VP. The exhaust pipe 34 is attached to the bottom portion 12b of the processing container 12. An exhaust apparatus 36 is connected to the exhaust pipe 34. The exhaust apparatus 36 includes a pressure controller and a vacuum pump such as, for example, a turbo-molecular pump. When the exhaust apparatus 36 is operated, gas may be exhausted from the outer periphery of the mounting table 14 through the exhaust passage VL so as to decompress the processing chamber S to a desired degree of vacuum.

As illustrated in FIGS. 1 and 2, the antenna 16 is installed above the mounting table 14. The antenna 16 introduces microwaves so as to excite the processing gas. In addition, in an exemplary embodiment, the plasma processing apparatus 10 may further include a microwave generator 38, a tuner 40, a wave guide 42, a mode converter 44, and a coaxial wave guide 46. The microwave generator 38 generates microwaves having a frequency of for example, 2.45 G Hz. The microwave generator 38 is connected to the top of the coaxial wave guide 46 through the tuner 40, the wave guide 42, and the mode converter 44.

The coaxial wave guide 46 includes an outer conductor 46a and an inner conductor 46b. The outer conductor 46a has a cylindrical shape extending in the axis Z direction using the axis Z as the central axis thereof. The lower end of the outer conductor 46a may be electrically connected to the upper portion of a cooling jacket 58 having a conductive surface. The inner conductor 46b is installed within the outer conductor 46a coaxially to the outer conductor 46a. The inner conductor 46b has a cylindrical shape extending in the axis Z direction. The lower end of the inner conductor 46b is connected to a second slot plate 56 of the antenna 16 which will be described below. As described below, the lower end of the inner conductor 46b is expanded diametrically to form a flange 46f which is connected to the second slot plate 56.

The antenna 16 includes a dielectric window 50. In an exemplary embodiment, the antenna 16 includes the dielectric plate 52, the first slot plate 54 and the second slot plate 56. The dielectric plate 52 is a substantially annular plate and is made of a dielectric material, for example, quartz. The dielectric plate 52 is sandwiched between the second slot plate 56 and the bottom surface of the cooling jacket 58. The wave guide formed between the inner conductor 46b and the outer conductor 46a is connected to a wave guide formed between the inner surface of the cooling jacket 58 and the inner conductor 46b which is in turn connected to a wave guide formed between the bottom surface of the cooling jacket 58 and the second slot plate 56. The dielectric plate 52 is disposed in the wave guide formed between the cooling jacket 58 and the top surface of the second slot plate 56, thereby reducing the wavelength of propagated microwaves.

The second slot plate 56 is a substantially disc-shaped member made of a metal. The first slot plate 54 is installed just below the second slot plate 56 to be in contact with the second slot plate 56. The first slot plate 56 is also a substantially disc-shaped member made of a metal. At the center of the second slot plate 56, a substantially circular through hole is formed and the inner conductor 46b extends through the circular through hole. At the center of the first slot plate 54, a through hole is also formed that is continuous to the through hole of the second slot plate 56. The flange 46f provided at the lower end of the inner conductor 46b is disposed within the through hole of the first slot plate 54. When the flange 46f comes into contact with the second slot plate 56, the inner conductor 46b and the second slot plate 56 are connected with each other.

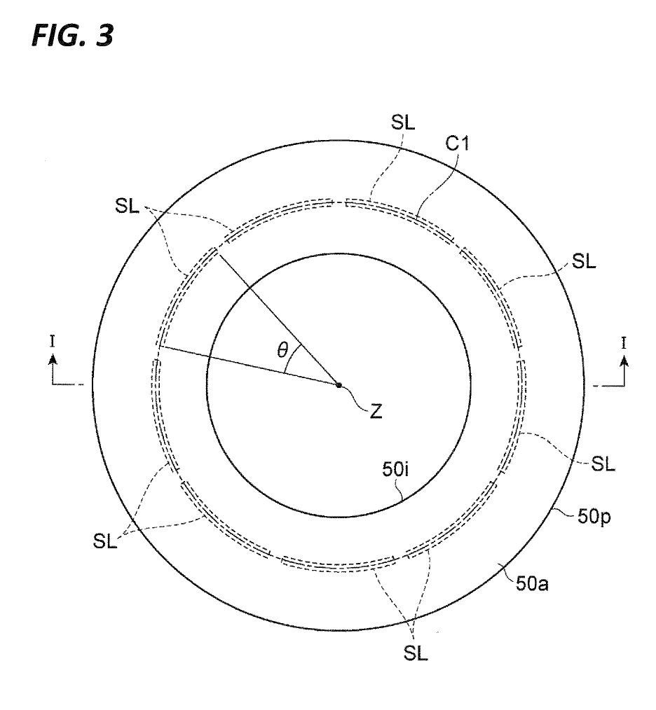

The first slot plate 54 and the second slot plate 56 are formed with a plurality of slots SL that penetrate the first and second slot plates 54, 56. FIG. 3 is a bottom view illustrating the bottom area and slots of the dielectric window. In addition, FIGS. 1 and 2 illustrates a cross-sectional configuration of the plasma processing apparatus 10 in the same plane as the cross-sectional plane taken along line I-I of FIG. 3. Hereinafter, reference will be made to FIG. 3 together with FIGS. 1 and 2.

The plurality of slots SL are arranged along a circular arc C 1 which is centered on the axis Z. The diameter of the circular arc C 1 is, for example, 410 mm when a wafer W1 of 450 mm is processed. Each of the plurality of slots SL has an arc shape in a plan view. The angle θ of each of the plurality of slots SL extending around the axis Z is, for example, 35°.

As illustrated in FIGS. 1 and 2, at an upper portion of each slot SL, that is, at a portion of each slot SL formed in the second slot plate 56, the dielectric plate 52 protrudes to fill the upper portion of the slot SL. In addition, at a lower portion of each slot SL, that is, at a portion of each slot SL formed in the first slot plate 54, a dielectric piece 60 is embedded. The dielectric piece 60 may be made of quartz like the dielectric plate 52.

The dielectric window 50 is provided below the slots SL. The dielectric window 50 is a substantially annular plate which is made of a dielectric material, for example quartz. The dielectric window 50 has a bottom area 50a. The bottom area 50a extends substantially in an annular shape around the axis Z. The dielectric window 50 adjoins the processing space S at the bottom surface region 50a. The bottom surface region 50a is defined by an inner edge 50i and an outer edge 50p. The diameter of the inner edge 50i of the bottom surface region 50a is, for example, 300 mm when processing a wafer W of 450 mm. Further, the diameter of the outer edge 50p of the bottom surface region 50a is, for example, 550 mm when processing the wafer W of 450 mm. The bottom surface region 50a is provided at an area vertically above the edge of the wafer W. Accordingly, the dielectric window 50 limits a region where the dielectric window 50 adjoins the processing space S to the bottom surface region 50a and limits a region where surface waves of microwaves are propagated to the bottom surface region 50a. As a result, in the plasma processing apparatus 10, the region just below the dielectric window 50 where plasma is generated may be limited to the region vertically just above the edge of the W.

In addition, as illustrated in FIGS. 1 and 2, plasma processing apparatus 10 further includes a gas shower unit 62. The gas shower unit 62 is disposed within a space defined by the inner peripheral surface of the annular dielectric window 50. The gas shower unit 62 includes a body 64 and a protection cover 66. The body 64 has a substantially cylindrical shape which is opened at the upper end. The upper end of the body 64 is connected to the first slot plate 54. The body 64 includes a shower plate unit 64 at the lower end side thereof. The shower plate unit 64a has a substantially circular shape in a plan view. Further, the processing space S side surface of the shower plate unit 64a is covered by the protection cover 66. The protection cover 66 is made of, for example, quartz. The protection cover 66 and the shower plate unit 64a are formed with a plurality of gas injection holes 62h that vertically penetrate the protection cover 66 and the shower plate unit 64a.

The body 64 of the gas shower unit 62 defines a gas diffusion chamber 62s together with the first slot plate 54. The plurality of gas injection holes 62h extend between the gas diffusion chamber 62s and the processing space S. In addition, the pipe 68 passes through the inner hole of the inner conductor 46b of the coaxial wave guide 46 in which one end of the pipe 68 is provided inside the gas diffusion chamber 62s. To the other end of the pipe 68, a first gas supply unit GS1 is connected. The first gas supply unit GS1 may include a gas source of the processing gas, a valve, and a flow rate controller such as a mass flow controller.

In the plasma processing apparatus 10, the processing gas supplied from the first gas supply unit GS1 arrives at the gas diffusion chamber 62s through the pipe 68 and is diffused in the gas diffusion chamber 62s. The processing gas diffused in the gas diffusion chamber 62s is introduced into the processing space S through the plurality of gas injection holes 62h. The processing gas introduced into the processing space S through the gas injection holes 62h of the gas shower unit 62 is supplied to a region in the vicinity of the dielectric window 50. That is, the processing gas is supplied to a plasma generation region having a high electron density. In addition, as described above, the gas shower unit 62 is provided in the inner space of the dielectric window 50 of a substantially annular shape so that the processing gas may be introduced through the gas injection holes 62h distributed a broad region centered on the axis Z. Accordingly, relatively uniform flow of the processing gas directed to the wafer W may be formed.

As illustrated in FIG. 1, in an exemplary embodiment, the plasma processing apparatus 10 may further include a peripheral introducing unit 70. The peripheral introducing unit 70 provides a plurality of gas injection holes 70h. The plurality of gas injection holes 70h supplies the processing gas mainly to the edge area of the wafer W. The plurality of gas injection holes 70h are opened toward the edge area of the wafer W or toward the edge area of the mounting region MR. The plurality of gas injection holes 70h are arranged below the gas shower unit 62 and above the mounting table 14 along the circumferential direction. That is, the plurality of gas injection holes 70h are arranged along the circumferential direction around the axis Z in a region (plasma diffusion region) having an electron temperature that is lower than that in the region just below the dielectric window 50. The peripheral introducing unit 70 may supply the processing gas toward the edge are of the wafer W in a state in which the processing gas is more suppressed in dissociation than the processing gas supplied from the gas shower unit 62.

In an exemplary embodiment, the peripheral introducing unit 70 may further include an annular pipe 72. The annular pipe 72 is formed with a plurality of gas injection holes 70h. The annular pipe 72 may be made of, for example, quartz. In an exemplary embodiment, the annular pipe 72 is installed along the inner surface of the side wall 12a as illustrated in FIG. 1. In other words, the annular pipe 72 is not disposed on the dielectric window 50 and the mounting region MR, that is on a route connecting the wafer W. Accordingly, the annular pipe 72 does not hinder the diffusion of plasma. Further, since the annular pipe 72 is installed along the inner wall surface of the side wall 12a, the annular pipe 72 is suppressed from being consumed by plasma so that the frequency of replacing the annular pipe 72 may be reduced.

One end of the pipe 74 is connected to the annular pipe 72. A second gas supply unit GS2 is connected to the other end of the pipe 74. The second gas supply unit GS2 may include a gas source of the processing gas, a valve, and a flow rate controller such as a mass flow controller. The processing gas supplied from the second gas supply unit GS2 may be a gas of which species is the same as the processing gas supplied from the first gas supply unit GS1 or a gas of which gas species partly or entirely different the processing gas supplied from the first gas supply unit GS2.

As illustrated in FIG. 1, in an exemplary embodiment, the plasma processing apparatus 10 may further include a driving mechanism configured to adjust the distance between the mounting table 14 and the dielectric window 50 in the axis Z direction by vertically moving the mounting table 14. Specifically, legs 80 are installed within a space surrounded by the bellows 28. The legs 80 extend in the axis Z direction in which the upper ends of the legs 80 are coupled to the bottom surface of the support unit 26 and the lower ends of the legs 80 are coupled to a plate portion 82a of a link 82.

The link 82 includes the plate portion 82a and to columnar portions 82b. The plate portion 82a is installed below the processing container 12. In an exemplary embodiment, the matching unit MU described above is attached to the plate portion 82a. Further, a through hole extending along the axis Z direction is formed at the center of the plate portion 82a and the support unit 26, and the power feeding rod PFR described above is connected to the plate 18 of the mounting table 14 through the through hole of the plate portion 82a and the through hole of the support unit 26.

The columnar portions 82b extend upwardly from the peripheral edge of the plate portion 82a. In addition, the columnar portions 82b extend substantially in parallel to the side wall 12a at the outside of the side wall 12a. A ball screw feeding mechanism is connected to the columnar portions 82b. Specifically, two screw shafts 84 extend substantially in parallel to the two columnar portions 82b at the outside of the side wall 12a. The screw shafts 84 are connected to two motors 86, respectively. Two nuts 88 are attached to the screw shafts 84, respectively. The two columnar portions 82b are coupled to the nuts 88, respectively.

With such a driving mechanism, when the motors 86 are rotationally driven, the nuts 88 are moved in the axis Z direction, i.e., in the vertical direction. According to the vertical movement of the nuts 88, the mounting table 14 indirectly supported by the link 82 may be moved in the axis Z direction, i.e. in the vertical direction. As a result, the distance in the axis Z direction between the mounting table 14 and the dielectric window 50 and hence, the distance in the axis Z direction between the wafer W and the dielectric window 50 may be adjusted.

In the plasma processing apparatus 10 described above, the region adjoining the processing space S in the dielectric window 50 is limited to the bottom surface region 50a and the bottom surface region 50a is formed in an annular shape, so that the region where the surface waves are propagated is limited to a region above the edge of the mounting region MR, i.e. to a region above the edge of the wafer W. Accordingly, even if the mode hop occurs, the plasma generating region is limited to the region just below the bottom surface region 50a. That is, the plasma generating region is limited to the region above the edge of the wafer W. Since the wafer W is processed by diffusing the plasma, the plasma processing apparatus 10 may reduce the variation in processing according to an in-plane position of the wafer W.

In addition, with the driving mechanism that realizes the vertical movement of the mounting table 14 as described above, the distance in the axis Z direction between the mounting table 14 and the dielectric window 50 may be adjusted. With this arrangement, the density distribution of plasma in the diametric direction just above the wafer W may be adjusted. For example, it may be possible to form a density distribution of plasma in which the plasma density just above the outer edge of the wafer W is higher than the plasma density just above the center of the wafer W, or a density distribution of plasma which is contrary thereto.

Hereinafter, descriptions will be made on results of various simulations which were performed so as to evaluate the plasma processing apparatus 10.

(Simulations 1 to 4)

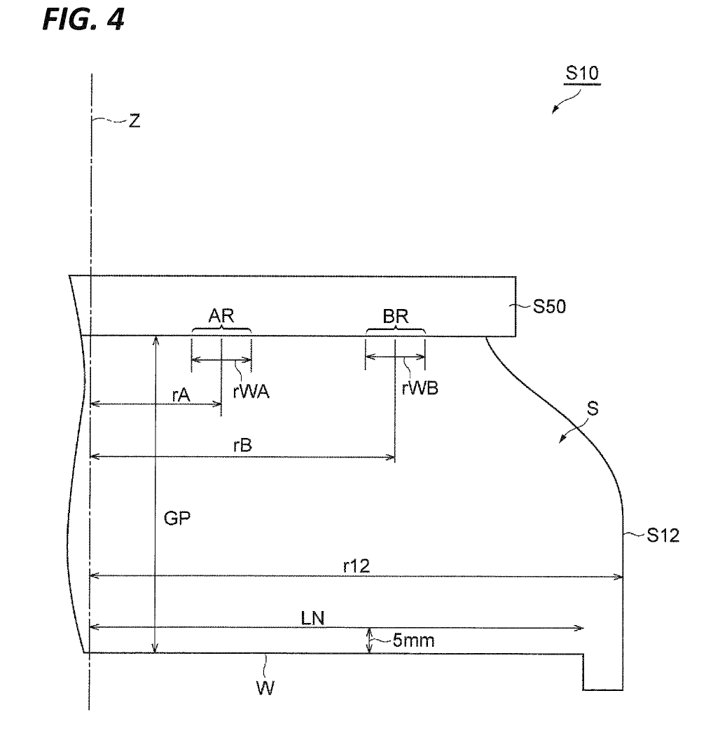

In Simulations 1 to 4, boundary conditions on the bottom surface of a dielectric window having a disc shape which is the same as the shape of a conventional dielectric window was changed to change a plasma generating position just below the dielectric window and then, uniformity of plasma density in the diametric direction just above the wafer was evaluated. FIG. 4 is a view schematically illustrating a plasma processing apparatus simulated in Simulation 1. As illustrated in FIG. 4, the plasma processing apparatus S10 simulated in Simulation 1 included a side wall S12 that defines a processing space S and a dielectric window S50. The side wall S12 formed a cylindrical shape extending in the axis Z direction around the axis Z and the radius r12 of the inner surface of the side wall S12 was 270 mm. In addition, the dielectric window S50 was formed substantially in a disc shape with a radius of 225 mm using quartz and the distance GP between the dielectric window S50 and the wafer W was set to 150 mm.

In Simulations 1 and 3, the boundary conditions were set such that plasma may be generated just below the region AR in the bottom surface of the dielectric window S50 and, in Simulations 2 and 4, the boundary conditions were set such that plasma may be generated just below the region BR in the bottom surface of the dielectric window S50. In addition, the distance rA from the axis Z to the diametric center of the region AR was set to 65 mm and the diametric width rWA of the region AR was set to 30 mm. Further, the distance rB from the axis Z to the diametric center of the region BR was set to 155 mm, and the diametric width rWB of the region BR was set to 30 mm. Moreover, in Simulations 1 and 2, the pressure within the processing space S was set to 20 mTorr (2.666 Pa) and, in Simulations 3 and 4, the pressure within the processing space S was set to 100 mTorr (13.33 Pa).

In each of Simulations 1 to 4, a plasma density at 5 mm just above the wafer W under the conditions as described above was calculated at each of a plurality of sample points on a line LN extending radially from the axis Z. In addition, in each of Simulations 1 to 4, diametric uniformity of the plasma densities was calculated from the plasma densities calculated at the plurality of sample points. Specifically, an average of the plasma densities at the plurality of sample points (Ave) and a standard deviation of the plasma densities at the plurality of sample points (SD) and then, SD/Ave was used as an index of uniformity of the plasma densities in the diametric direction. As a result, SD/Ave values calculated in Simulations 1 to 4 were 39%, 28%, 45%, and 15%, respectively.

Both Simulation 1 and Simulation 2 were simulations in which the pressure of the processing space S was set to 20 mTorr. However, the SD/Ave value of Simulation 1 in which the plasma was generated in the region AR was smaller than the SD/Ave value of Simulation 2 in which the plasma was generated in the region BR which is outside the region AR. Further, both Simulation 3 and Simulation 4 were simulations in which the pressure of the processing chamber S was set to 100 mTorr. However, similar to the results of Simulations 1 and 2, the SD/Ave value of Simulation 3 in which the plasma was generated in the region AR was smaller than the SD/Ave value of Simulation 4 in which the plasma was generated in the region BR which is outside the region AR. From this, it was confirmed that, when plasma is generated at a position located farther away from the axis Z, the uniformity in plasma densities in the diametric direction just above the wafer W is enhanced. Accordingly, it was confirmed that, when the plasma generating position is limited to a region just below the annular bottom surface region 50a, the uniformity of plasma densities in the diametric direction just above the wafer W is enhanced.

(Simulations 5 to 10)

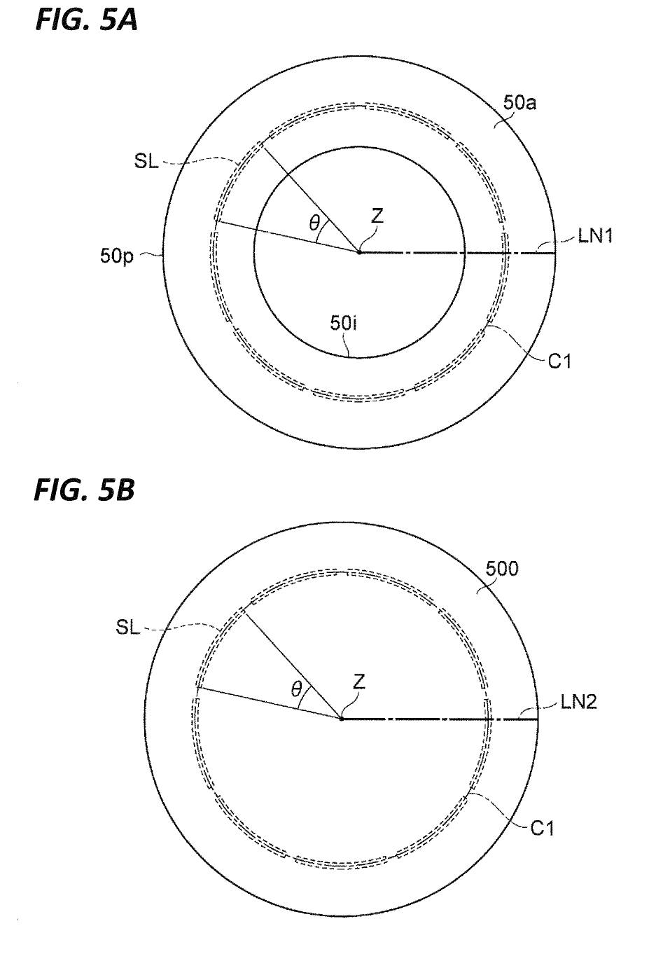

FIGS. 5A and 5B are bottom views illustrating the bottom surface region and slots of the dielectric window for describing settings of Simulations 5 to 10. In Simulations 5 to 7, the plasma processing apparatus 10 was simulated and electric field strength in the bottom surface region 50a of the dielectric window 50 was simulated.

Specifically, in Simulations 5 to 7, nine slots SL)(θ=35°) were arranged along arc circles C1 having a diameter of 410 mm, the dielectric window 50 made of quartz was disposed just below the slots SL, and a system to which microwaves of 2.45 GHz were introduced was set in the dielectric window 50. In addition, in Simulations 5 to 7, the diameter of the inner edge 50i of the bottom surface region 50a was set to 300 mm and the diameter of the outer edge 50p was set to 550 mm. Further, the thickness of the dielectric window 50 was set to λ/4 (λ is the wavelength of the microwaves). Further, in Simulations 5 to 7, the electron densities of the space S were set to 8×10¹⁶ (m⁻³), 5×10¹⁷ (m⁻³) and 1×10¹⁸ (m⁻³), respectively. Moreover, in Simulations 5 to 7, the electric field strength distributions in the bottom surface region 50a were calculated.

In Simulations 8 to 10, a system which is different from that in Simulations 5 to 7 in that the dielectric window (indicated by symbol 500 in the drawing) has a disc shape as illustrated in FIG. 5B was set and the electric field strength distributions in the bottom surface of the dielectric window were calculated. In addition, the electron densities of the processing space S in Simulations 8 to 10 were 8×10¹⁶ (m⁻³), 5×10¹⁷ (m⁻³) and 1×10¹⁸ (m⁻³), respectively. Further, in Simulations 5 to 10, assuming that uniform plasma is generated in the processing space S and the processing space S is filled with a dielectric material, a dielectric constant ∈ₚ represented by Equation (1) as follows was used as a physical property value of plasma.

$$\begin{matrix}Equation ( 1 ) & \\ {ɛ}_{p} [ F \text{/} m ] = {ɛ}_{0} ( 1 - \frac{{ω}_{p}^{2}}{ω ( ω - i {V}_{e} )} ) & ( 1 )\end{matrix}$$

Here, ∈₀ is a dielectric constant of vacuum and w=2.45 GHz. Further, Vₑ and ωₚ are electron density functions, and each frequency of plasma ωₚ was calculated according to Equation (2).

$$\begin{matrix}Equation ( 2 ) & \\ {ω}_{p} [ rad \text{/} s ] = \sqrt{\frac{{e}^{2} [ {C}^{2} ] {n}_{e} [ \# \text{/} {m}^{3} ]}{{ɛ}_{0} [ F \text{/} m ] {m}_{e} [ kg ]}} & ( 2 )\end{matrix}$$

Further, Vₑ was calculated according to Equation (3) as follows using a collision frequency of electrons and argon.

Equation (3)

Vₑ=Kₑnₙₑᵤₜᵣₐₗ (3)

In addition, kₑ is an elastic collision coefficient of electrons and argon and nₙₑᵤₜᵣₐₗ is a gas density. e is a unit electric charge, nₑ is an electron density, and mₑ is a mass of an electron.

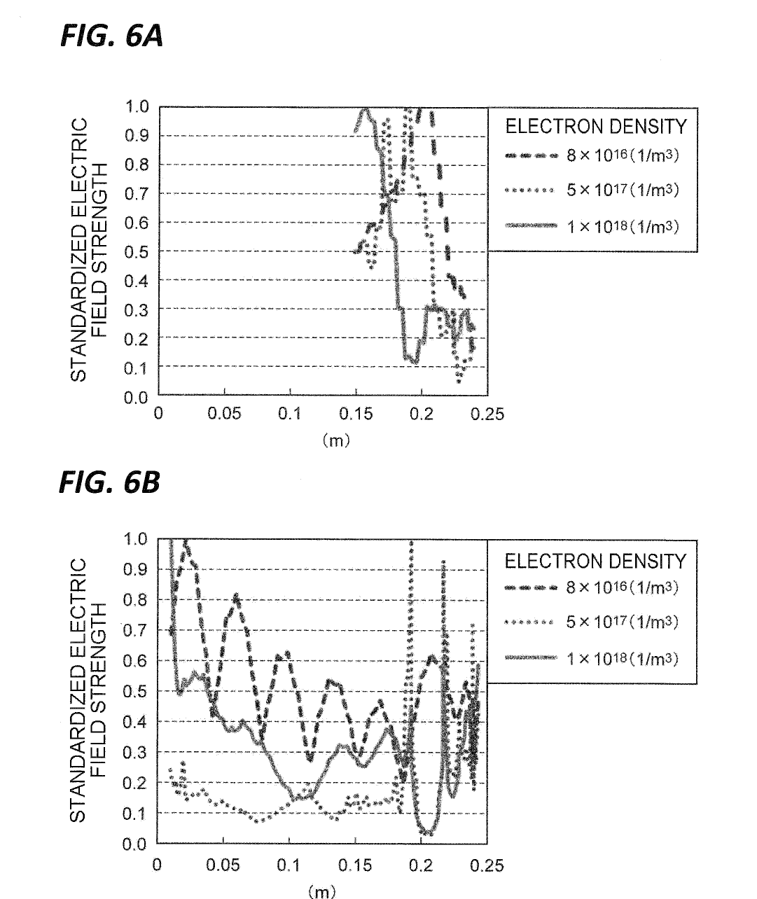

FIGS. 6A and 6B are graphs that represent electric field strength distributions calculated in Simulations 5 to 10. FIG. 6A is a graph that represents electric field strength distributions calculated in Simulations 5 to 7 in which the electric field strength distributions in the bottom surface region 50a of the dielectric window 50 are represented along the line LN1 extending diametrically from the axis Z (see, e.g., FIG. 5A). In FIG. 6A, the vertical axis represents an electric field strength that is standardized as a maximum value on the line LN1 and the horizontal axis represents a distance from the axis Z. In addition, FIG. 6B is a graph that represents electric field strength distributions calculated in Simulations 8 to 10 in which the electric field strength distributions in the bottom surface of the dielectric window are represented along the line LN2 extending diametrically from the axis Z (see, e.g., FIG. 5B). In FIG. 6B, the vertical axis represents an electric field strength that is standardized as a maximum value on the line LN2 and the horizontal axis represents a distance from the axis Z.

As illustrated in FIG. 6B, from the results of Simulations 8 to 10, it was confirmed that, when the electron density of the processing space (S) is changed, the electric field strength distribution is largely varied in the bottom surface of the dielectric window, that is, the mode hop occurs and thus, the position where an electric field with a high strength occurs is varied over the bottom surface of the disc-shaped dielectric window. Meanwhile, as illustrated in FIG. 6A, from the results of Simulations 5 to 7, it was confirmed that, with the dielectric window 50 of the plasma processing apparatus 10, the mode hop occurs when the electron density is changed but the position where an electric field with a high strength occurs is limited to a boundary between the bottom surface region 50a and plasma. Accordingly, it was confirmed that, with the dielectric window 50 of the plasma processing apparatus 10, the plasma generating position is limited to an area just below the bottom surface region 50a.

(Simulation 11)

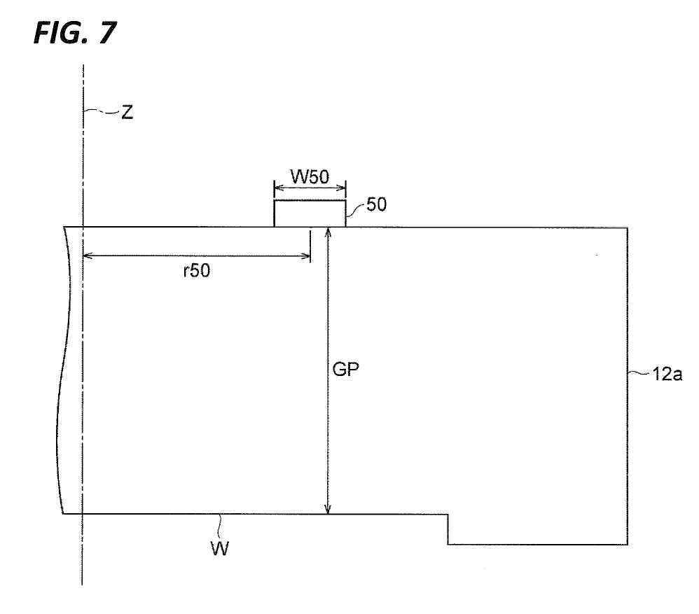

FIG. 7 is a view for describing a system set in Simulation 11. In Simulation 11, plasma density distributions at 5 mm just above the wafer W were calculated while variously changing the distance GP in the axis Z direction between the bottom surface of the dielectric window 50 configured by an annular plate made of quartz and the wafer W, and the distance r50 of the diametrical center of the dielectric window 50 from the axis Z. In addition, the distance W50 between the inner edge and the outer edge of the dielectric window 50 was set to 40 mm, the diameter of the wafer W was set to 450 mm, and the distance between the inner surface of the side wall 12a of the processing container 12 and the axis Z, i.e. the diameter of the inner surface of the side wall 12a was set to 750 mm.

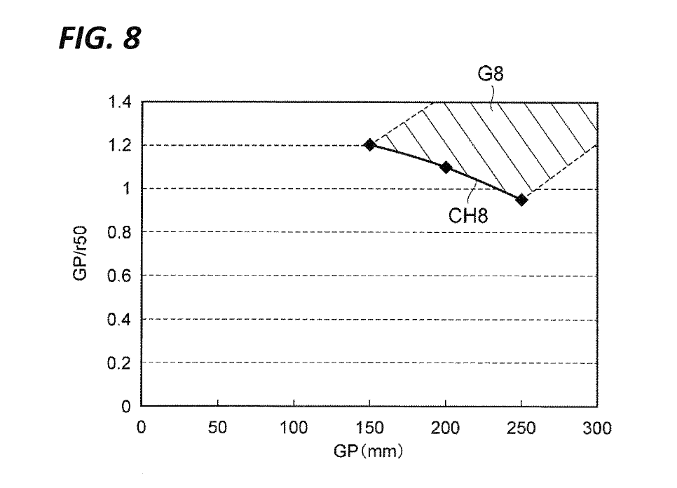

FIG. 8 is a graph that represents the results calculated by Simulation 11. In the graph illustrated in FIG. 8, the horizontal axis represents GP and the vertical axis represents GP/r50. In addition, the solid line CH8 indicated in the graph of FIG. 8 represents a relationship between GP and GP/r50 in a case in which it may be considered that the plasma density in the diametric direction at 5 mm just above the wafer W is approximately uniform. In addition, the hatched region G8 in FIG. 8 represents that the plasma density just above an edge of the wafer W becomes higher than the plasma density just above the center of the plasma density when a combination of GP and GP/r50 is included in the region G8. Further, at a combination of GP and GP/r50 included in the region opposite to the region G8 with reference to the solid line CH8, the plasma density just above the center of the wafer W becomes higher than the plasma density just above the outer edge of the wafer W.

As illustrated in FIG. 8, from Simulation 11, it was confirmed that the plasma density distribution just above the wafer W may be adjusted by adjusting the distance between the wafer W and the bottom surface region 50a of the dielectric window 50. Accordingly, from Simulation 11, the above-described driving mechanism of the mounting table 14 is effective.

In addition, in order to reduce variation of a processing according to an in-plane position of the wafer W, it is required in general that the variation of plasma density just above the wafer W in the diametrical direction be reduced or the plasma density just above the edge of the wafer W be increased higher than the plasma density just above the center of the wafer W. Accordingly, it is considered desirable in general to use the distance GP in the axis Z direction between the bottom surface of the dielectric window 50 specified by the solid line CH8 or the region G8 in FIG. 8 and the wafer W.

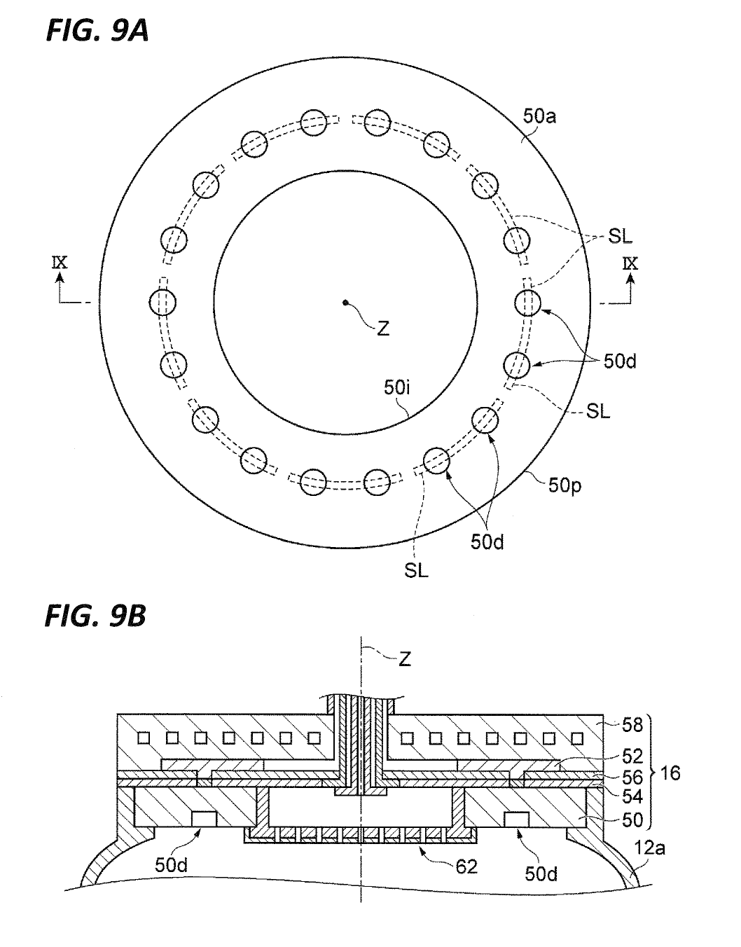

Although various exemplary embodiments and simulations of the plasma processing apparatus have been described above, various modified aspects may be made without being limited to the exemplary embodiments as described above. For example, the shape of the dielectric window 50 is not limited to the above-described exemplary embodiments. For example, as for the dielectric window, the dielectric window illustrated in FIGS. 9A and 9B may be used. FIGS. 9A and 9B are views for describing a plasma processing apparatus according to another exemplary embodiment.

FIG. 9A is a bottom view illustrating the bottom surface and slots of the dielectric window and FIG. 9B is a cross-sectional view illustrating an upper portion of the plasma processing apparatus according to another exemplary embodiment. The FIG. 9B is a cross-sectional view corresponding to a cross section taken along line IX-IX of FIG. 9A.

The plasma processing apparatus illustrated in FIGS. 9A and 9B is different from the plasma processing apparatus 10 illustrated in FIG. 1 in that a plurality of recesses 50d are formed on the bottom surface of the dielectric window 50. The plurality of recesses 50d are arranged in the circumferential direction around the axis Z. The recesses 50d may be provided vertically below the slots SL. With the plasma processing apparatus illustrated in FIGS. 9A and 9B, the plasma generating position may be limited to the inside of the recesses 50d. Accordingly, the plasma generating position may be stabilized.

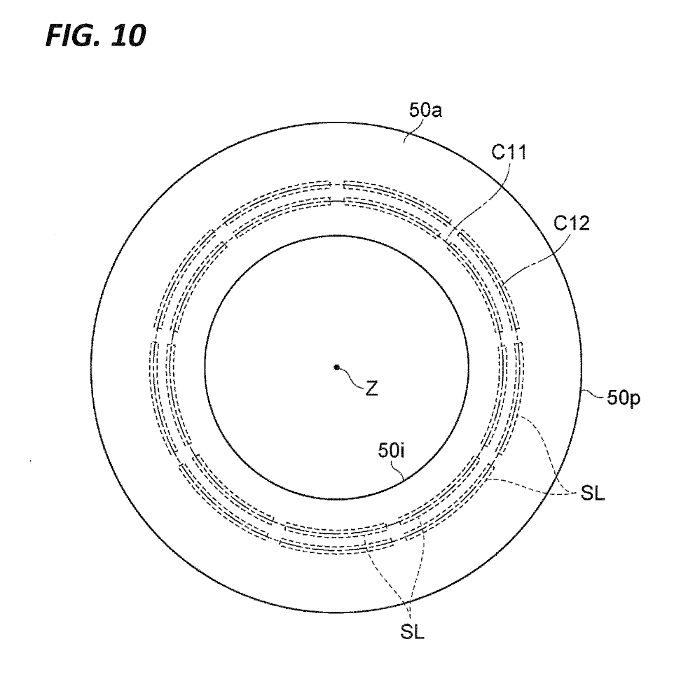

FIG. 10 is a bottom view illustrating the bottom surface region and slots of the dielectric window in a plasma processing apparatus according to still another exemplary embodiment. As illustrated in FIG. 10, in the plasma processing apparatus, a group of slots among a plurality of slots SL are arranged along a circular arc C11 and another group of slots among the plurality of slots SL are arranged along a circular arc C12 of which the diameter is larger than that of the circular arc C11. In this manner, a plurality of groups of slots may be arranged along a plurality of concentric circular arcs, respectively.

Further, the angular range 0 of each slot SL extending in the circumferential direction and the number of slots arranged along one circular arc may be optionally changed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus that generates plasma of a processing gas to process a workpiece, the plasma processing apparatus comprising:
a processing container configured to define a processing space;
a mounting table including a mounting region where a workpiece accommodated in the processing container is mounted; and
a microwave introducing antenna,
wherein the microwave introducing antenna includes a dielectric window installed above the mounting table, and
the dielectric window includes a bottom surface region that adjoins the processing space, the bottom surface region being formed in an annular shape to limit a region where a surface wave is propagated to a region above an edge of the mounting region.

2. The plasma processing apparatus of claim 1, further comprising a mechanism configured to adjust a distance between the mounting table and the dielectric window.

3. The plasma processing apparatus of claim 1, wherein the bottom surface region of the dielectric window includes a plurality of recesses arranged in a circumferential direction.

4. The plasma processing apparatus of claim 3, wherein the microwave introducing antenna includes a slot plate which is formed with a plurality of slots configured to radiate a microwave in relation to the dielectric window,
the plurality of slots are arranged along one or more circular arcs above the bottom surface region, and
the plurality of recesses are provided to be positioned vertically below the plurality of slots.
